(19) United States
(12) Patent Application Publication
(10) Pub. No.: US 2011/0062023 A1
(43) Pub. Date: Mar. 17, 2011

(54) SPUTTERING DEVICE

(75) Inventor: Chung-Pei Wang, Tucheng (TW)

(73) Assignee: HON HAI PRECISION INDUSTRY CO., LTD., Tu-Cheng (TW)

(21) Appl. No.: 12/700,932

(22) Filed: Feb. 5, 2010

(30) Foreign Application Priority Data
Sep. 15, 2009 (CN) 200910307030.6

(51) Int. Cl. C23C 14/50

(52) U.S. Cl. 204/298.15

(57) ABSTRACT

A sputtering device includes a housing, two baffles, a pair of conveyor, and a support. The housing includes a chamber therein. The baffles are slidably installed in the chamber of the housing to divide the chamber of the housing into a number of separated rooms where workpieces are treated. The baffles are slideable relative to the housing between a first position where the rooms are isolated and sealed by the baffles from others, and a second position where the rooms communicate with each other. The support is received in the housing. The pair of conveyor is mounted on the housing for transporting the support from one of the rooms to another.

### BACKGROUND

1. Technical Field

The disclosure relates to a coating device, and particularly, to a sputtering device.

2. Description of Related Art

In order to form multilayer films on workpieces, various sputtering devices are employed in coating treatment of workpieces. Commonly, sputtering devices are separated from each other. Accordingly, the workpieces to be processed need to be transported from one sputtering device to another. However, the coating process is prone to deteriorate due to transportation, thereby negatively impacting efficiency. Furthermore, the workpieces are exposed less than ideal environmental conditions leading among other things to contamination and/or spontaneous oxidized film being formed on the workpieces.

What is needed is a sputtering device addressing the above-mentioned problems.

### BRIEF DESCRIPTION OF THE DRAWINGS

FIG. 1 is an isometric view of a sputtering device according to an exemplary embodiment.

FIG. 2 is an isometric exploded view of the sputtering device of FIG. 1.

FIGS. 3 and 4 show the work status of the sputtering device of FIG. 1.

### DETAILED DESCRIPTION

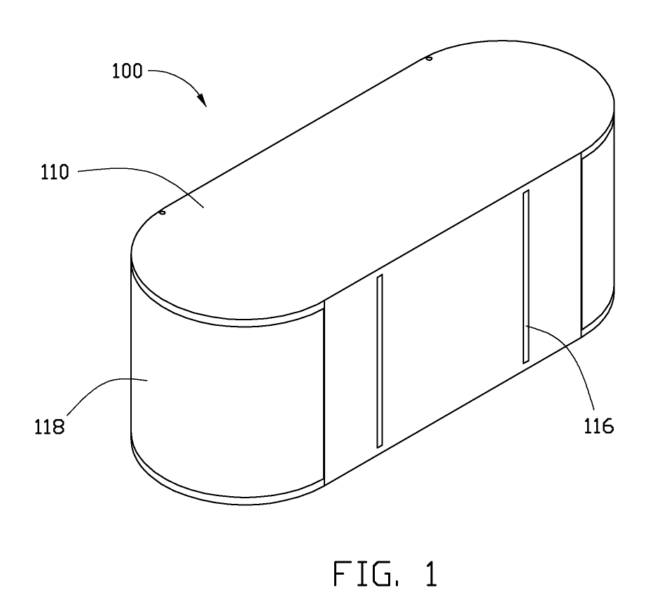

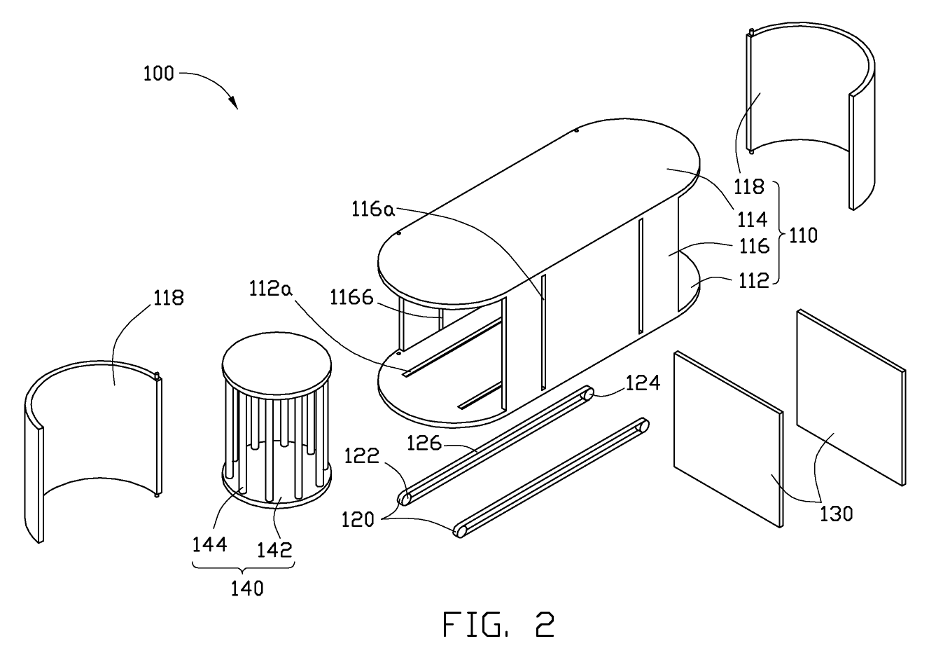

Referring to FIGS. 1 and 2, a sputtering device 100 according to an exemplary embodiment of the present disclosure is shown. The sputtering device 100 includes a housing 110, a pair of conveyors 120, two baffles 130, and a workpiece support 140. The housing 110 defines a chamber (not labeled) therein. The conveyor 120 and the workpiece support 140 are accommodated in the housing 110. The conveyor 120 is mounted on the bottom of the housing 110 for transporting the support 140 in the housing 110. The baffles 130 are slidably installed on the housing 110, provided for dividing the chamber of the housing 110 into a number of separated rooms. The baffles are slidable relative to the housing between a first position where the rooms are isolated and sealed by the baffles 130 from the others, and a second position where the rooms communicate with each other. The support 140 can be transported from one room to another by the conveyor 120.

The housing 110 has a rectangular box-like construction and includes a bottom 112 and a top 114, two sidewalls 116 connected between the bottom 112 and the top 114, and a pair of doors 118 mounted at two opposite ends of the housing 110 to allow workpieces to move in and out of the housing 110. A pair of first slits 116a is perforated in one of the sidewalls 116 for disposing the baffles 130, and a pair of blind slits 116b is defined in the other one of the sidewalls 116 corresponding to the first slits 116a for engagingly receiving a distal end of the baffles 130. A pair of parallel channels 112a is defined on the bottom 112, each for receiving one of the conveyers 120.

Each of the conveyers 120 includes a motor 122, a roller 124 and a belt 126 looped over the motor 122 and the roller 124. The motor 122 and the roller 124 of each conveyer 120 are oppositely mounted in one of the channels 112a. The motor 122 can drive the belt 126 along the channel 112a. The support 140 is loaded on the belt and transported by the belt from one room to another.

The baffles 130 are slidably insertable into the housing 110 through the first slits 116a and stopped in the blind slits 116b to divide the inner space of the housing 110 into a number of such as three isolated rooms where the workpieces are treated. Each room is provided with a controllable cathode supporting assembly (not shown) for depositing a layer on the surfaces of the workpieces. The baffles 130 can also be drawn out from the housing 110 thereby allowing the workpieces to be transported from one room to another.

The support 140 includes a pair of opposite plates 142, and a number of poles 144 connecting the plates 142. Each pole supports the workpieces thereon. Exemplarily, the plates 142 are annular.

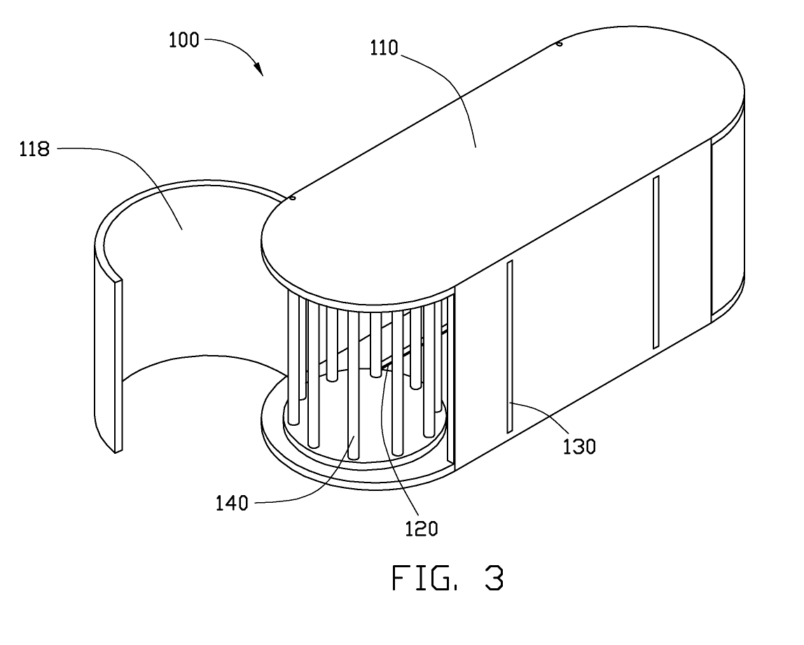

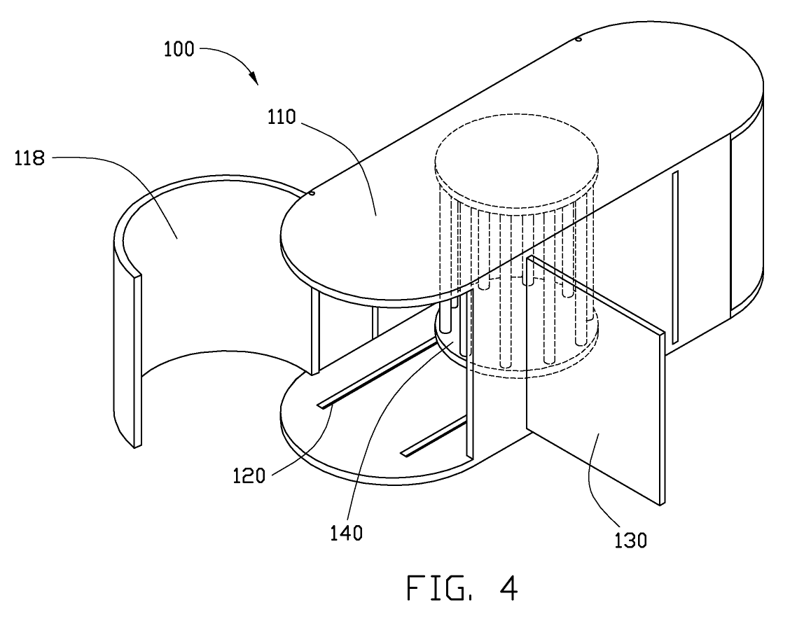

Referring to FIGS. 3 and 4, in use, one of the doors 118 is opened, and the support 140 with a number of workpieces held thereon is loaded into a first room. The door 118 is closed, and the workpieces are treated in the first room. Afterwards, one of the baffles 130 is drawn out through the first slot 116a thereby the support 140 is transported by the conveyer 120 to a second room adjacent to the first room, where the workpieces undergo another treatment. The drawn baffle 130 is inserted into the housing 110 again to isolate the second room from the first room. Afterwards, the support 140 is transported to a third room after the second room, where the workpieces undergo further treatment. After the treatment, the other door 118 is opened and the workpieces are downloaded from the support 140.

In the present disclosure, all processing steps for the workpieces can be successively implemented in the rooms isolated by the baffles 130. In addition, the workpieces are isolated from outside the housing 110 throughout the treatments and transportations thereby improving quality of the films formed on the workpieces.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A sputtering device comprising:
a housing having a chamber therein;
at least two baffles slidably installed in the housing to divide the chamber of the housing into a plurality of separated rooms where the workpieces are treated; wherein the baffles are slidable relative to the housing between a first position where the rooms are isolated and sealed by the baffles from the others, and a second position where the rooms communicate with each other;
a support received in the housing;
a pair of conveyors mounted in the housing for transporting the support from one of the rooms to another.

2. The sputtering device of claim 1, wherein the housing comprises a top and a bottom, two sidewalls connected between the bottom and top, and a pair of doors pivotally mounted at two opposite ends of the housing to allow workpieces to move in and out of the housing.

3. The sputtering device of claim 2, wherein at least two first slits are perforated in one of the sidewalls; the baffles are inserted into the housing through the first slits.

4. The sputtering device of claim 3, wherein at least two blind slits are defined in the other one of the sidewalls corresponding to the first slits; each blind slit is configured for engagingly receiving a distal end of one of the baffles.

5. The sputtering device of claim 4, wherein the bottom of the housing defines a pair of parallel channels therein; the conveyers are installed in the channels.

6. The sputtering device of claim 5, wherein each of the conveyers comprises a motor and a roller oppositely mounted in the channel, and a belt looped over the motor and the roller; and the support is carried by the belt.

7. The sputtering device of claim 6, wherein the support comprises a pair of parallel plates, and a plurality of poles connecting the plates.

8. The sputtering device of claim 7, wherein the plates are annular.
